(19) United States
(12) Patent Application Publication
(10) Pub. No.: US 2003/0233977 A1
(43) Pub. Date: Dec. 25, 2003

(54) Method for forming semiconductor processing components

(76) Inventors: Yeshwanth Narendar, Westford, MA (US); Edmund L. Mastrovito, Worcester, MA (US)

Correspondence Address: ZAGORIN O'BRIEN & GRAHAM LLP, 401 W 15TH STREET, SUITE 870, AUSTIN, TX, 78701, US

(21) Appl. No.: 10/176,202

(22) Filed: Jun. 20, 2002

(51) Int. Cl. C30B 23/00; C30B 25/00; C30B 28/12; C30B 28/14

(52) U.S. Cl. 117/109

(57) ABSTRACT

A method is disclosed for forming a silicon carbide component. The method calls for providing a preform, including carbon, purifying the preform to remove impurities to form a purified preform, and exposing the purified preform to a molten infiltrant which includes silicon. According to the foregoing method, the molten infiltrant reacts with the carbon to form silicon carbide. The silicon carbide component formed according to this method may be particularly suitable for use in semiconductor fabrication processes, as a semiconductor processing component.

### CROSS-REFERENCE TO RELATED APPLICATION(S)

### BACKGROUND

1. Field of the Invention

The present invention relates generally to methods for forming silicon carbide components using carbon preforms, and more particularly to methods for forming silicon carbide semiconductor process components used in the manufacture of semiconductor devices.

2. Description of the Related Art

Various semiconductor processing components are used to handle semiconductor wafers during batch processing as well as during single wafer processing. Such components are also known in the art as ‘handling implements’ or ‘workpieces,’ particular examples including conventional quartz wafer boats, paddles, carriers, and the like. State of the art semiconductor processing components are formed of silicon carbide (SiC), such as recrystallized silicon-silicon carbide (Si—SiC). Si—SiC components offer the advantage of being mechanically stable at the elevated temperatures at which various semiconductor processing steps are carried out.

Si—SiC components are manufactured through SiC powder processing techniques, where SiC powder and appropriate binders are formed into appropriate shapes and heat treated. The SiC powder is commercially produced using well-known electro-thermal reactive processes by reacting mined or natural quartz and petroleum coke in furnace houses. Typically, SiC powder produced according to this process has high impurity levels, due to impurities in the raw materials and impurities introduced during comminution processes. The impurity levels in the SiC powder may easily be several orders of magnitude above the maximum impurity levels needed for use in semiconductor fabrication environments.

As is understood in the art, semiconductor fabrication is a time-consuming and highly precise process, during which cleanliness of the working environment is of utmost importance. In this regard, semiconductor “fabs” include various classes of clean-rooms having purified air flows to reduce incidence of airborne particle contaminants. With increased integration and density of semiconductor devices, and attendant shrinking of photolithographic patterns on the semiconductor die, it has become increasingly important to safeguard the cleanliness of the processing environment. In view of the impurity levels of silicon carbide powders, the powder (or the shaped bodies formed of silicon carbide powder) is typically exposed to a purification process.

Specifically, the SiC powder is exposed to a reactive agent, such as HF or HNO₃ acids, or NaOH followed by exposure to at least one of sulfuric acid and nitric acid. Alternatively, the shaped SiC component is exposed to HF, HCl, and/or HNO₃ acid treatments, optionally at elevated temperatures. While such treatments are effective at reducing impurity concentration in the SiC powder or shaped part, impurities such as Al and B that are present in the SiC lattice, and transition metal silicides and carbides, remain after purification.

The shaped SiC component is typically coated with silicon for porosity reduction, then are further coated with a CVD SiC layer. The CVD SiC layer is a critical layer, and functions to seal the surface and inhibit loss of silicon near the surface of the component. Importantly, the CVD SiC layer functions as a diffusion barrier to prevent migration of impurities contained in the body of the component to the outer surface of the component, where such impurities would otherwise cause contamination of the semiconductor fabrication environment.

The present inventors have recognized numerous deficiencies with state of the art Si—SiC semiconductor processing components. While in theory the CVD SiC layer should function effectively as a diffusion barrier, in practice the CVD SiC layer is prone to defects that are difficult to detect, and which can severely compromise its efficacy as a diffusion barrier. For example, the CVD SiC layer is prone to pinhole defects, may have sub-optimal thickness or varying thicknesses throughout the layer, and may be subject to spalling or chipping due to thermal or handling stresses. In addition, the CVD layer substantially increases manufacturing costs, particularly for components used in newer generation 300 mm wafer-based processing fabs. In addition, the roughness of the CVD layer at the portions of the component that contact the wafers may cause crystallographic slip (deformation), particularly in 300 mm wafers processed at elevated temperatures. In an attempt to overcome crystallographic slip deficiencies, the art has generally deposited a thick CVD layer and executed subsequent surface machining steps to reduce roughness and thickness at the wafer contact areas. These additional steps introduce even higher manufacturing costs and complexity.

Accordingly, in view of the deficiencies associates with the state of the art semiconductor process components, a need exists in the art for improved components.

### SUMMARY

In one aspect of the present invention, a method is provided for forming a silicon carbide component. The method calls for providing a preform, including carbon, purifying the preform to remove impurities to form a purified preform, and exposing the purified preform to a molten infiltrant which includes silicon. According to the foregoing method, the molten infiltrant reacts with the carbon to form silicon carbide. In another aspect of the present invention, a silicon carbide component is provided, which is formed according to the foregoing method. The silicon carbide component may be particularly suitable for use in semiconductor fabrication processes, as a semiconductor processing component.

### DESCRIPTION OF THE PREFERRED EMBODIMENT(S)

Turning to the details of embodiments of the present invention, a method is provided for forming a silicon carbide component through a preform process, in which a carbon-based preform is provided. The carbon preform is purified according to a particular feature of the present invention, and the purified preform is then exposed to a molten infiltrant, particularly molten silicon, whereby the silicon reacts with the carbon to form silicon carbide. The silicon carbide component formed according to embodiments of the present invention finds particular use in the process flow for forming semiconductor devices, such as a semiconductor wafer handling workpiece or implement.

More particularly, the particular form of the semiconductor processing component according to embodiments of the present invention may vary, and includes single wafer processing and batch processing components. Single wafer processing components include, for example, bell jars, electrostatic chucks, focus rings, shadow rings, chambers, susceptors, lift pins, domes, end effectors, liners, supports, injector ports, manometer ports, wafer insert passages, screen plates, heaters, and vacuum chucks. Examples of semiconductor processing components used in batch processing include, for example, paddles (including wheeled and cantilevered), process tubes, wafer boats, liners, pedestals, long boats, cantilever rods, wafer carriers, vertical process chambers, and dummy wafers.

As stated above, embodiments of the present invention provide a carbon preform. The carbon preform may be manufactured according to any one of several techniques. Typical processing steps for forming the preform through a carbon precursor route, described in more detail below.

A mixture including a carbon material, furfuryl alcohol or tetrahydrofurfuryl alcohol, and a polyethylene oxide polymer are formed into a mixture, and cast into a mold to form a cast body. The body is then heated to decompose the polymer and form a preform. Typical compositions of the mixture may include about 30 to about 80 volume percent of the carbon material, up to 50 volume percent furfuryl or tetrahydrofurfuryl alcohol, and about 1 to 10 volume percent of the polyethylene oxide polymer. The furfuryl alcohol or tetrahydrofurfuryl alcohol adds plasticity and strength to the green body formed by molding the mixture, while the polyethylene oxide polymer increases the viscosity of the mixture so as to maintain a fairly homogeneous suspension of the carbon material after mixing. The polyethylene oxide polymer may have a molecular weight range from about 100,000 to about 5,000,000.

The particular form of the carbon material may be chosen from one of several commercially available powders, provided that the powder chosen has minimized impurity concentrations, so as to minimize the extent of purification required according to embodiments of the present invention. For example, the carbon material includes amorphous carbon, single crystal carbon, polycrystalline carbon, graphite, carbonized binders such as epoxy, plasticizers, polymer fibers such as rayon, polyacrylonitrile, and pitch. Preferably, the mixture, and hence, the subsequently formed preform, has minimized impurity levels, and contains no metals or metal alloys, and no ceramic materials. Particularly, it is preferred that each reactive metal such as molybdenum, chromium, tantalum, titanium, tungsten, and zirconium, are minimized, such as into the less than 10 ppm range, preferably less than the 5 ppm. Preferably, the foregoing metals are restricted to the foregoing ranges in total. In addition, it is preferable that the silicon content in the mixture and the subsequently formed preform is also minimized, at least below a level of 5 weight percent, and preferably, less than 1 weight percent.

After mixing, the mixture can be cast into a mold and dried to allow the liquid in the mixture to evaporate. After drying, the molded body is generally heated at an elevated temperature, such as within a range of about 50 to 150° C. to cross-link the polymer and strengthen the preform. In place of the furfuryl alcohol contained in the mixture, or in addition to the furfuryl alcohol contained in the mixture, a phenolic resin or furan derivative may additionally be exposed to and absorbed by the molded preform. The furan derivative includes furan, furfuryl, furfuryl alcohol, or tetrahydrofurfuryl alcohol, and aqueous solutions containing furfuryl alcohol or tetrahydrofurfuryl alcohol. The additional exposure and absorption of the furan derivative or phenolic resin provide additional green strength to the molded body, and further control over final density, pore size, and pore size distribution of the preform.

Following drying and heating, the molded body may be machined in its green state, if desired. Then, the molded body is heated at a temperature within a range of about 600° C. to about 1400° C., preferably about 900° C. to 1000° C. to decompose the polymer and the furan derivative, leaving behind a carbon preform containing mainly carbon. Although it is desirable to utilize materials in the process for forming the preform to completely eliminate any impurities contained therein, it is pragmatically difficult to do so. Accordingly, the preform may unavoidably contain a trace amount of impurities. These impurities might include metallic impurities such as aluminum (Al) and boron (B).

In one embodiment of the present invention, the preform has an open porosity structure, which includes an interconnected network of pores, voids or channels that are open to the surface of the preform and that extend through the body of the preform. Preferably, the preform has minimal closed porosity, pores that are not open to the surface of the preform and which are not in contact with the ambient atmosphere. According to an embodiment of the present invention, the preform has a bulk density not greater than about 1.0 g/cc, and not less than about 0.5 g/cc, such as not greater than about 0.95 g/cc and not less than about 0.45 g/cc. In addition, the preform typically has a porosity within a range of about 35 vol % to about 70 vol %, and has an average pore size within a range of about 0.1 to about 100 microns.

In one embodiment, prior to purification as discussed below, the density may be increased by additional treatment steps. This is desirable in cases where the as-formed preform has less than ideal target density. The density may be increased by exposure to an carbon containing or carbon precursor impregnant, which is capable of wicking into the preform. Multiple impregnation steps may be carried out prior purification, that is, multiple cycles may be carried out. Typically the impregnate is a liquid, such as a resin, including a phenolic resin dissolved in a carrier.

According to a particular feature of embodiments of the present invention, the carbon preform is purified to remove impurities and form a purified preform. The purification step is generally carried out by heating the preform to an elevated temperature at which impurities contained in the preform are volatilized. For example, the preform may be heated under a vacuum to a temperature of at least about 1700° C., typically at least about 1800° C. to volatilize impurities contained in the preform. The preform is heated for a period of time that is effective to remove impurities from the preform, to an impurity level not greater than 100 ppm, preferably less than 50 ppm, in the purified preform. Typically, the impurity level is reduced to be not greater than 10 ppm. The time period during which heating is carried out is typically greater than 2 hours, more typically greater than about 3 hours. Certain embodiments call for heating periods of not less than 4 hours. Alternatively, the preform may be heated to a lower temperature while introducing a reactive gas in the heating chamber to aid in removal of the impurities contained in the preform. For example, the preform may be heated to at least about 1100° C. while under vacuum and while introducing a reactive gas. The heating step may be carried out for a period effective to remove the impurities, such as at least about 3 hours, typically greater than 4 hours. Certain embodiments were heated for a time period greater than 6 hours. The reactive gas may include a halogen species, such as chlorine (Cl) and/or fluorine (F), and includes carbon halides. In the case of chlorine, the chlorine may be in the form of chlorine gas (Cl₂), hydrochloric acid (HCl), CCl₄ or CHCl₃, any of which may be diluted with a suitable portion of an inert gas, such as He, N₂, or Ar. In a similar manner, fluorine may be in the form of hydrofluoric acid (HF), and can be diluted with a suitable proportion of a non-reactive gas such as nitrogen (N₂) or argon (Ar).

According to a particular feature of embodiments of the present invention, purification of a carbon-based preform is more effective than any attempts at purifying a silicon carbide-based component. In particular, the solubility limits for common impurities such as Al and B are substantially lower in a carbon body than a silicon carbide body. In addition, metallic impurities are more easily volatilized and removed from carbon than from silicon carbide. Further, at the temperatures noted above to effect volatilization of the impurities, silicon carbide, unlike carbon, breaks down into Si and Si_{X}C_{Y} vapors and solid C under vacuum. Accordingly, high temperature purification cannot be effectively executed because of the undesirable breakdown of silicon carbide. Silicon carbide also exhibits rapid grain growth and coarsening at the purification temperatures noted above. This grain growth and coarsening of the silicon carbide negatively impacts the structural stability and integrity of the component. In contrast, the carbon-based preform according to embodiments of the present invention does not decompose and vaporize, or exhibit excessive grain growth.

Furthermore, silicon carbide decomposition at the elevated purification temperatures tends to consume reactive halogen gases, thereby further reducing effectiveness of purification of silicon carbide. On the other hand, carbon does not detrimentally consume the reactive halogen gases.

Following purification, the purified preform is then exposed to a molten infiltrant including silicon, whereby the infiltrant reacts with the carbon to form silicon carbide. According to a feature of the present invention, this exposure to molten infiltrant takes place subsequent to the purification step, as the purification of silicon carbide (formed via exposure to the infiltrant) is problematic as discussed above.

Generally, the molten infiltrant consists of a highly pure silicon source, such as solar-grade or semiconductor-grade silicon. In particular, any trace impurities present in the silicon infiltrant are kept below a concentration of about <5 ppm, preferably, no greater than 1 ppm. Since the melting point of silicon is about 1410° C., infiltration of the purified preform with the molten silicon is typically carried out above that temperature, such as with a range of about 1500° C. to about 1900° C. The actual mechanism by which the infiltrant is exposed to the purified preform can widely vary, provided that the molten silicon comes into contact with an outer surface of the purified preform, whereby capillary action is effective to pull the molten infiltrant into the network of pores of the purified preform. The silicon source can be pool of molten Si metal contained in a graphite crucible or a compact containing Si and purified carbon. The molten metal can be infiltrated by direct contact with the Si source or preferably by using a compatible porous high purity interface made from carbon or graphite.

The resulting silicon carbide of the resulting component is generally beta-silicon carbide. For example, the major phase of the silicon carbide is beta, and typically the silicon carbide is at least 90 wt % beta silicon carbide, the balance being phases other than beta, more typically at least 95 wt % beta silicon carbide.

### EXAMPLES

### Example 1

Carbon black powder was mixed with 5 to 25 wt % of phenolic novalak resin and the resulting mixture was dried to a powder. Samples were formed from the carbon-phenolic mixture by uni-axially pressing to a density of 0.55 g/cc to 0.65 g/cc. The pressed samples were cured at 225° C. for 4 hours to obtain sufficient green strength for handling and green machining. Subsequently, the samples were heated to 1000° C. for 2 hours to convert the resin to carbon powder.

After carbon conversion, the samples were heated in dry 25-100% HCl gas between 1100° C. to 1300° C. for 3 to 8 hours to purify the carbon preforms. The purification process reduced the total metallic impurities between 2.5-15 ppm.

The purified samples were infiltrated with molten Si metal between 1450-1600° C. in vacuum between 0.2-10 torr. The samples were placed in a purified graphite crucible with Si chips for the impregnation process. The Si infiltrated into the pores of the carbon preform, reacting with carbon to form SiC and filling the residual porosity with metallic Si. The siliconized samples have densities between 2.75-3.00 g/cc depending on the starting preform density and the amount of resin added.

### Example 2

A commercially available carbon preform based on chopped rayon fibers (procured from Calcarb Corporation) was impregnated with phenolic resin dissolved in IPA. Multiple impregnation cycles were conducted to increase the preform density from to 0.45-0.6 g/cc. The impregnated samples were cured at 225° C. for 4 hours to increase green strength and heat treated at 1000° C. in Ar to pyrolyze the resin into carbon.

The pyrolyzed carbon preform was cleaned in hot 100% HCl at 1300° C. for 6 hours. Infiltration with molten Si was performed at 1650° C. in 2 torr vacuum for 4 hours to form high purity siliconized SiC with a density between 2.6-2.7 g/cc.

As described above, the silicon carbide component formed according to embodiments of the present invention takes on the form of one of various semiconductor processing components. In this regard, multiple purified and infiltrated silicon carbide components can be assembled together to form a single semiconductor processing component. Alternatively, a single silicon carbide component can form the semiconductor processing component, such as in the case of a semiconductor processing component having a fairly simple geometric shape. Further, multiple purified preforms may be assembled together prior to infiltration, which together form the semiconductor processing component, or a sub-assembly of a semiconductor processing component, such as in the case of highly complex geometrically shaped processing components.

In certain circumstances, components of the present invention may carry additional surface coatings prior to installation in the semiconductor processing fab. For example, it may be desirable to deposit a polysilicon layer, a silicon oxide layer, a silicon nitride layer, a metallic layer, a photoresist layer or some other layer upon the component prior to using that component in a semiconductor fabrication process. In the past, if such a layer was desired by the semiconductor manufacturer, the layer was deposited by the manufacturer after removal from any packaging and prior to use of the component in the process flow. To avoid such additional processing steps by the semiconductor manufacturer, an embodiment of the present invention provides for deposition of one or more desired layers on the component surface, prior to packaging the component for shipping or storage.

While embodiments of the present invention have been described above with particularity, it is understood that those skilled in the art may make modifications to such embodiments while still within the scope of the following claims. For example, while the foregoing description refers to forming semiconductor processing components, embodiments of the present invention may be used in connection with other components as well, including ceramic handling components used in manufacturing settings other than the semiconductor field.

What is claimed is:

1. A method for forming a silicon carbide component, comprising:
providing a preform comprising carbon;
purifying the preform to remove impurities to form a purified preform; and
exposing the purified preform to molten infiltrant comprising silicon, whereby the molten infiltrant reacts with the carbon to form silicon carbide.

2. The method of claim 1, wherein the preform comprises mainly carbon.

3. The method of claim 2, wherein the preform consists essentially of carbon and a trace amount of impurities.

4. The method of claim 2, wherein the preform contains less than 5 wt % silicon.

5. The method of claim 1, wherein prior to purifying the preform, a density of the preform is increased.

6. The method of claim 5, wherein the density of the preform is increased by impregnating the preform.

7. The method of claim 6, wherein the preform is impregnated with a carbon containing impregnant.

8. The method of claim 1, wherein the preform is formed by firing a carbon-based green body.

9. The method of claim 8, wherein the carbon-based green body contains carbon powder and a binder, and the step of firing removes the binder.

10. The method of claim 8, wherein the carbon-based green body contains an organic precursor, and the step of firing decomposes the organic precursor to carbon.

11. The method of claim 10, wherein the organic precursor comprises a phenolic or furan based resin.

12. The method of claim 8, wherein the carbon-based green body is fired at a temperature within a range of about 600° C. to about 1400° C.

13. The method of claim 1, wherein the preform is purified by heating the preform under vacuum.

14. The method of claim 13, wherein the purified preform has an impurity level of not greater than 100 ppm.

15. The method of claim 14, wherein the impurity level is not greater than 50 ppm.

16. The method of claim 14, wherein the impurity level is not greater than 10 ppm.

17. The method of claim 13, wherein the preform is heated at a purification temperature for a time period effective to remove impurities from the preform to an impurity level not greater than 10 ppm in the purified preform.

18. The method of claim 13, wherein the preform is heated to a temperature of at least about 1700° C. to volatilize the impurities.

19. The method of claim 18, wherein the preform is heated to a temperature of at least about 1800° C. to volatilize the impurities.

20. The method of claim 18, wherein the preform is heated at said temperature for at least about 2 hours

21. The method of claim 20, wherein the time period is at least about 3 hours.

22. The method of claim 13, wherein the preform is further exposed to a reactive gas to purify the preform.

23. The method of claim 22, wherein the preform is heated to a temperature of at least about 1100° C. while under said vacuum and while being exposed to said reactive gas.

24. The method of claim 23, wherein the preform is heated at said temperature for at least 3 hours.

25. The method of claim 24, wherein the time period is at least about 4 hours.

26. The method of claim 22, wherein the reactive gas comprises a halogen-containing gas.

27. The method of claim 26, wherein the reactive gas comprises Cl or F.

28. The method of claim 27, wherein the reactive gas is a carbon halide.

29. The method of claim 28, wherein the carbon halide comprises CCl₄ or CHCl₃.

30. The method of claim 1, wherein the preform has a bulk density not greater than about 1.0 g/cc.

31. The method of claim 1, wherein the preform has a bulk density not less than about 0.5 g/cc.

32. The method of claim 1, wherein the preform has an interconnected network of pores, and the molten infiltrant infiltrates the preform through the interconnected network.

33. The method of claim 32, wherein the preform has a porosity of within a range of about 35% to about 70%.

34. The method of claim 32, wherein the average pore size of the preform is within a range of about 0.1 microns to about 100 microns.

35. The method of claim 1, wherein the silicon carbide component is a semiconductor processing component.

36. The method of claim 35, wherein the semiconductor processing component is selected from the group consisting of bell jars, electrostatic chucks, focus rings, shadow rings, susceptors, lift pins, domes, end effectors, liners, supports, injector ports, manometer ports, wafer insert passages, screen plates, heaters, vacuum chucks, wheeled paddles, cantilevered paddles, process tubes, wafer boats, liners, pedestals, long boats, cantilever rods, wafer carriers, process chambers, and dummy wafers.

37. The method of claim 35, wherein multiple silicon carbide components are assembled together to form the semiconductor processing component.

38. The method of claim 35, wherein multiple purified preforms are assembled together prior to exposure to the molten infiltrant.

39. The method of claim 1, wherein the purified preform is exposed to the molten infiltrant at a temperature within a range of about 1500° C. to 1900° C.

40. The method of claim 1, wherein the molten infiltrant consists essentially of silicon.

41. The method of claim 1, wherein molten infiltrant consists of silicon and trace impurities.

42. The method of claim 41, wherein the trace impurities are present in the infiltrant at a concentration no greater than 5 ppm.

43. The method of claim 42, wherein the molten infiltrant comprises solar or semiconductor grade silicon.

44. A silicon carbide component formed by:
providing a preform comprising carbon;
purifying the preform to remove impurities to form a purified preform; and
exposing the purified preform to molten infiltrant comprising silicon, whereby the molten infiltrant reacts with the carbon to form silicon carbide.
